(19) United States
(12) Patent Application Publication
(10) Pub. No.: US 2011/0141426 A1
(43) Pub. Date: Jun. 16, 2011

(54) LIQUID CRYSTAL PANEL UNIT AND METHOD FOR INSPECTING SAME

(76) Inventor: Atsushi Okada, Osaka (JP)

(21) Appl. No.: 13/058,491

(22) PCT Filed: Aug. 3, 2009
(86) PCT No.: PCT/JP2009/063725

§ 371 Date: Feb. 10, 2011

(30) Foreign Application Priority Data
Aug. 11, 2008 (JP) 2008207187

(51) Int. Cl. G02F 1/1345; G01R 31/26; G09G 3/36

(52) U.S. Cl. 349/150; 324/760.01; 345/87

(57) ABSTRACT

Provided are a liquid crystal panel unit having a liquid crystal panel and a flexible printed circuit connected to each other and a method for inspecting the same with which continuity between an electrode terminal on a panel substrate of the liquid crystal panel and a wiring pattern of the flexible printed circuit can be checked with a simple and reliable method. A liquid crystal panel (3) that has a panel substrate (2) and an opposite substrate (1) disposed opposite the panel substrate (2) via a liquid crystal layer, and a flexible printed circuit (10) in which a connection portion (14) of a wiring pattern (13) is connected to an electrode terminal (4) formed on the panel substrate (2) are provided. The electrode terminal (4) has an electrode inspection region (8) that is exposed in a state where the flexible printed circuit (10) is connected, and an opening portion (17) that exposes the wiring pattern (13) is formed in a base film (11) of the flexible printed circuit (10).

### TECHNICAL FIELD

The present invention relates to a liquid crystal panel unit provided with a liquid crystal panel and a flexible printed circuit connected to a panel substrate of the liquid crystal panel, and a method for inspecting the same, and in particular to a liquid crystal panel unit and a method for inspecting the same, with which an inspection for continuity between the panel substrate and the flexible printed circuit can be easily and reliably performed.

### BACKGROUND ART

A panel substrate that constitutes a liquid crystal panel has various electric circuit elements formed on the inner surface thereof, such as a pixel electrode that constitutes a unit of image display, a switching element for applying predetermined electric charge to the pixel electrode, metal wiring, and other control elements.

Electrode terminals drawn out from the metal wiring formed in an image display region where an image is displayed are provided in the vicinity of an edge portion of the panel substrate of the liquid crystal panel, and a wiring pattern of a flexible printed circuit (FPC) is connected to the electrode terminals, thereby forming a liquid crystal panel unit.

An edge portion of the flexible printed circuit is connected to the panel substrate of the liquid crystal panel, whereas the other edge portion thereof on the opposite side is connected to a peripheral circuit board that generates various signals for image display that are supplied to the panel substrate, a power supply voltage for the electric circuit elements formed on the panel substrate, and the like. Further, a circuit element for giving a predetermined signal to the panel substrate is often mounted on the flexible printed circuit connected to the panel substrate of the liquid crystal panel.

FIG. 5 is a cross-sectional view showing the configuration of a portion where a panel substrate and a flexible printed circuit of a conventional liquid crystal panel unit are connected to each other.

As shown in FIG. 5, a conventional liquid crystal panel unit 500 has a panel substrate 2 on which an electrode terminal 4 is formed, and a flexible printed circuit 50 in which a wiring pattern 53 is connected to the electrode terminal 4.

On the panel substrate 2 that constitutes a liquid crystal panel, the electrode terminal 4 drawn out from a region in which a liquid crystal layer (not shown) is formed to the edge portion of the panel substrate 2 is formed. Note that on the panel substrate 2, a portion of the electrode terminal 4 drawn out to a region that is not covered with an opposite substrate (not shown) other than the portion thereof on which the flexible printed circuit 50 is laminated is covered with an insulation protective film 5.

The flexible printed circuit 50 is obtained by forming the wiring pattern 53 made of metal foil such as copper foil on a base film 51 and, furthermore, covering the surface of the wiring pattern 53 with a protective layer 52. A portion of the edge portion of the flexible printed circuit 50 connected to the electrode terminal 4 on the panel substrate 2 is a connection portion 54 where an opening is formed in the protective layer 52, and thereby the wiring pattern 53 is exposed. A film material called an ACF (anisotropic conductive film) and having a resin layer 55 that includes conductive particles 56 is attached to this opening portion, and alignment and disposition are performed such that the exposed surfaces of the electrode terminal 4 and the wiring pattern 53 are opposite each other. After that, the connection portion is pressed with a constant pressure applied thereto, thereby bringing the conductive particles 56 in the ACF into contact with both the electrode terminal 4 and the wiring pattern 53, and thus electric connection therebetween is obtained. Also, the panel substrate 2 and the flexible printed circuit 50 are physically fixed by the resin layer 55 of the ACF.

Conventionally, a method called an impression inspection method is used in the inspection for checking whether or not the liquid crystal panel and the flexible printed circuit that constitute such a liquid crystal panel unit are connected to each other in a normal manner. This impression inspection method is a method for monitoring the sandwiching of the conductive particles in the ACF between the electrode terminal on the panel substrate and the wiring pattern of the flexible printed circuit by monitoring the portion joined by the ACF in the direction shown by the white arrow in FIG. 5 on the back face side of the liquid crystal panel, and is a method for determining the quality of connection based on the shape of the observed conductive particles and the number thereof, for example.

### DISCLOSURE OF INVENTION

### Problem to be Solved by the Invention

However, the above impression inspection method is a method for checking conductive particles by visual observation or by performing image processing on a captured image, and thus is merely a method for indirectly evaluating the connection between the electrode terminal and the wiring pattern. Accordingly, quantitative measurement cannot be performed, and also the overlooking of defects cannot be completely eliminated.

Further, in order to check a minute electrode terminal, observation needs to be performed in a state where the electrode terminal is magnified using a microscope, and thus a large number of terminals cannot be inspected at the same time, which also results in a problem with inspection efficiency.

In view of this, the present invention, in consideration of the above problems, aims to provide a liquid crystal panel unit having a liquid crystal panel and a flexible printed circuit connected to each other and a method for inspecting the same, with which continuity between an electrode terminal on a panel substrate of the liquid crystal panel and a wiring pattern of the flexible printed circuit can be checked using a simple and reliable method.

### Means for Solving Problem

In order to solve the above problems, a liquid crystal panel unit of the present invention includes a liquid crystal panel that has a panel substrate and an opposite substrate disposed opposite the panel substrate via a liquid crystal layer, and a flexible printed circuit in which a connection portion of a wiring pattern is connected to an electrode terminal formed on the panel substrate. The electrode terminal has an electrode inspection region that is exposed in a state where the flexible printed circuit is connected, and an opening portion that exposes the wiring pattern is formed in a base film of the flexible printed circuit.

A method for inspecting the liquid crystal panel unit of the present invention is a method for inspecting a liquid crystal panel unit including a liquid crystal panel that has a panel substrate and an opposite substrate disposed opposite the panel substrate via a liquid crystal layer, and a flexible printed circuit in which a connection portion of a wiring pattern is connected to an electrode terminal formed on the panel substrate, the method including detecting a resistance value between an electrode inspection region of the electrode terminal that is exposed in a state where the flexible printed circuit is connected and a wiring inspection region of the wiring pattern that is exposed by an opening portion being formed in a base film of the flexible printed circuit.

### Effects of the Invention

According to the present invention, continuity between an electrode terminal on a panel substrate of a liquid crystal panel and a wiring pattern of a flexible printed circuit can be checked using a simple and reliable method.

### BRIEF DESCRIPTION OF DRAWINGS

FIG. 1 is a diagram showing the schematic configuration of a liquid crystal panel unit according to an embodiment of the present invention.

FIG. 2 is an enlarged plan view showing a portion of the liquid crystal panel unit according to the embodiment of the present invention where a panel substrate and a flexible printed circuit are connected to each other.

FIG. 3 is a cross-sectional configuration diagram showing the portion of the liquid crystal panel unit according to the embodiment of the present invention where the panel substrate and the flexible printed circuit are connected to each other.

FIG. 4 is a diagram showing an inspection procedure of a method for inspecting the liquid crystal panel unit according to the embodiment of the present invention.

FIG. 5 is a diagram showing a method for inspecting a conventional liquid crystal panel unit.

### DESCRIPTION OF THE INVENTION

A liquid crystal panel unit according to the present invention includes a liquid crystal panel that has a panel substrate and an opposite substrate disposed opposite the panel substrate via a liquid crystal layer, and a flexible printed circuit in which a connection portion of a wiring pattern is connected to an electrode terminal formed on the panel substrate. The electrode terminal has an electrode inspection region that is exposed in a state where the flexible printed circuit is connected, and an opening portion that exposes the wiring pattern is formed in a base film of the flexible printed circuit.

With this configuration, since both the electrode inspection region of the electrode terminal and the wiring pattern at the opening portion are exposed in a state where both the electrode terminal and the wiring pattern are connected to each other, electric continuity between the electrode terminal and the wiring pattern can be directly determined.

Further, in the liquid crystal panel unit having the above configuration, it is preferable that the opening portion is formed at a position where the flexible printed circuit overlaps the panel substrate in a state where the flexible printed circuit is connected to the panel substrate. In this way, in the case where a measuring terminal is brought into contact with the wiring pattern exposed by the opening portion, reliable contact of the measuring terminal with the wiring pattern can be secured.

A method for inspecting the liquid crystal panel unit according to the present invention is a method for inspecting a liquid crystal panel unit including a liquid crystal panel that has a panel substrate and an opposite substrate disposed opposite the panel substrate via a liquid crystal layer, and a flexible printed circuit in which a connection portion of a wiring pattern is connected to an electrode terminal formed on the panel substrate, the method including detecting a resistance value between an electrode inspection region of the electrode terminal that is exposed in a state where the flexible printed circuit is connected and a wiring inspection region of the wiring pattern that is exposed by an opening portion being formed in a base film of the flexible printed circuit.

With this configuration, since both the electrode inspection region of the electrode terminal and the wiring inspection region of the wiring pattern are exposed in the state where the panel substrate of the liquid crystal panel and the flexible printed circuit are connected to each other, a resistance value therebetween can be directly detected electrically.

It is preferable that a resistance value between the electrode terminal on the panel substrate and the wiring pattern of the flexible printed circuit is detected by bringing an inspection probe terminal into contact with each of the electrode inspection region and the wiring inspection region. In this way, electric continuity between the probe terminals can be reliably detected.

Moreover, it is preferable that the wiring inspection region is positioned in a portion where the flexible printed circuit and the panel substrate overlap in a state where the flexible printed circuit is connected to the panel substrate. In this way, reliable contact of the wiring inspection region with a jig used for measurement can be obtained.

Below is a description of an embodiment of the present invention with reference to the drawings.

Note that, to facilitate description, the diagrams referenced below show only main members necessary to describe the present invention among constituent members of the embodiment of the present invention in a simplified manner. Accordingly, a display device according to the present invention may be provided with arbitrary constituent members that are not shown in the referenced diagrams. Further, the dimensions of the members in the diagrams do not necessarily faithfully represent the dimensions of the actual constituent members, the dimension ratio of the members, and the like.

FIG. 1 is a plan view showing the schematic configuration of a liquid crystal panel unit according to the present embodiment.

As shown in FIG. 1, a liquid crystal panel unit 100 according to the present embodiment is provided with a liquid crystal panel 3 having an opposite substrate 1 and a panel substrate 2 that are both made of glass arranged opposite each other with a liquid crystal layer (not shown) sandwiched therebetween, and flexible printed circuits 10 connected to the panel substrate 2 of the liquid crystal panel 3.

For color image display, color filters corresponding to respective pixels and an opposing electrode that applies a predetermined voltage to the liquid crystal layer are formed on the inner surface of the opposite substrate 1 of the liquid crystal panel 3. Further, pixel electrodes are disposed in a matrix on the inner surface of the panel substrate 2, forming a plurality of rows and a plurality of columns. The pixel electrodes form a display region where an image is displayed in the liquid crystal panel 3. In the display region of the panel substrate 2, there are formed a plurality of gate lines disposed in the row direction of the pixel electrodes, a plurality of source lines disposed in the column direction thereof, and further, TFTs disposed in the vicinity of points of intersection of the gate lines and the source lines orthogonal to each other and connected to respective pixel electrodes. Note that illustration with regard to the internal structure of the opposite substrate 1 and the panel substrate 2 is omitted.

The panel substrate 2 has a slightly larger surface area than that of the opposite substrate 1, and the surface thereof is exposed at portions in both the right and left directions of the liquid crystal panel 3 and on the lower side thereof, as shown in FIG. 1. In the region where the surface is exposed, electrode terminals (not shown in FIG. 1) for applying a predetermined voltage and signals are drawn out, the electrode terminals being connected to various wiring such as gate lines and source lines and electric circuit elements such as TFTs formed on the surface of the panel substrate 2. The wiring pattern (not shown in FIG. 1) of the flexible printed circuits 10 is connected to the electrode terminals, thereby forming the liquid crystal panel unit 100 in which the liquid crystal panel 3 and the flexible printed circuits 10 are connected to each other.

In the case where the liquid crystal panel 3 of the liquid crystal panel unit 100 is a so-called transmissive panel or semi-transmissive panel, a backlight that emits irradiation light necessary to display an image with the liquid crystal panel 3 is disposed on the back face side of the liquid crystal panel 3, and is housed together with the liquid crystal panel unit 100 in the interior of a bezel that is a frame-shaped mechanism member having a bottom, thereby forming a liquid crystal module together with peripheral circuits connected to the flexible printed circuits 10.

Note that although FIG. 1 shows the flexible printed circuits 10 connected to the panel substrate 2 as being spread as they are around the periphery thereof, when the liquid crystal panel unit 100 is incorporated in the bezel as the above liquid crystal module, the flexible printed circuits 10 are bent along the side face of the bezel and fixed on the back face of the bezel in order to reduce the external shape of the liquid crystal module.

Although FIG. 1 shows an example in which the plurality of flexible printed circuits 10 are connected to each of the three sides of the peripheral portion of the panel substrate 2, the liquid crystal panel unit 100 of the present invention is not limited to this. Specifically, the case where the flexible printed circuits 10 are connected only to any one side of the panel substrate 2, and the case where the flexible printed circuits 10 are connected to two sides or all four sides are not excluded. Further, there is also no limitation in the number of the flexible printed circuits 10 connected to the panel substrate 2, and the case in which only one flexible printed circuit 10 is connected to the panel substrate 2 is possible.

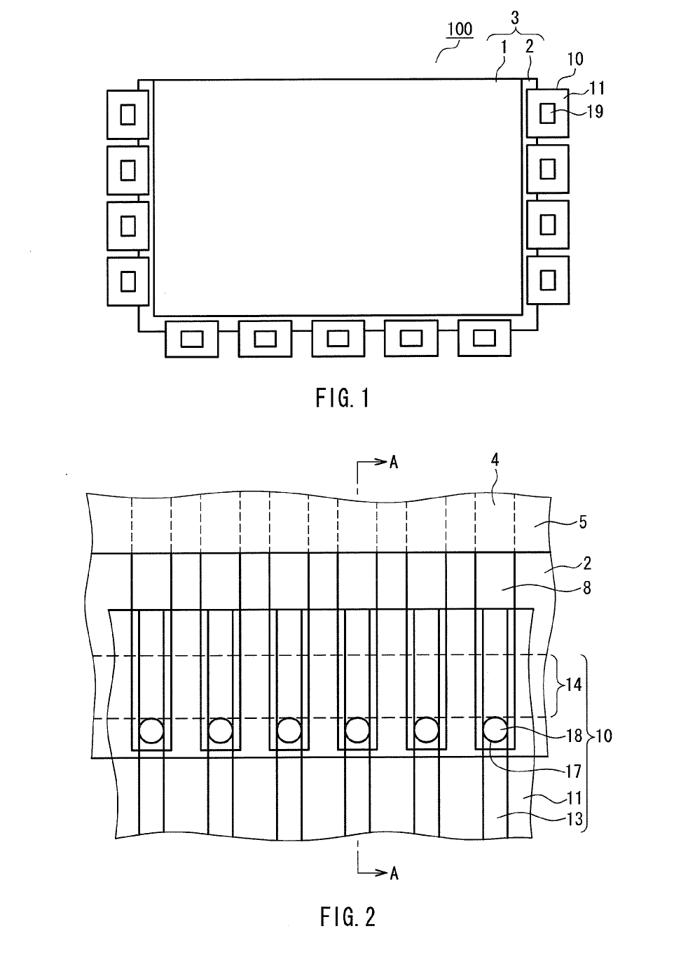

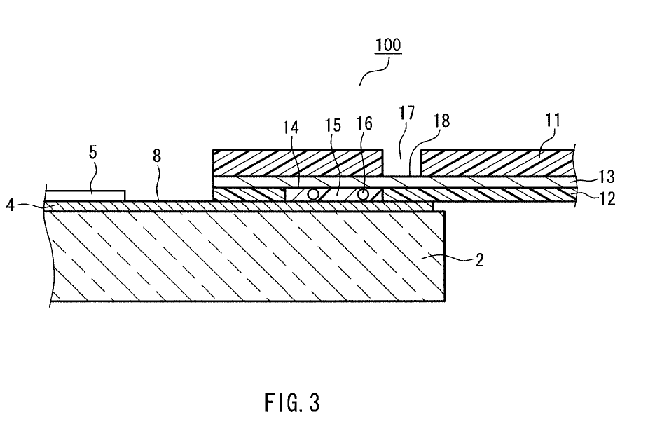

Next is a description of a portion of the liquid crystal panel unit 100 according to the embodiment of the present invention where the panel substrate 2 and a flexible printed circuit 10 are connected to each other, using FIGS. 2 and 3.

FIG. 2 is an enlarged plan view of a portion at an edge portion of the panel substrate 2 of the liquid crystal panel unit 100 according to the present embodiment where electrode terminals 4 and a flexible printed circuit 10 are connected to each other, viewed in the display direction of the liquid crystal panel 3.

As shown in FIG. 2, the plurality of electrode terminals 4 are formed substantially parallel to each other in the vicinity of the edge portion of the panel substrate 2 of the liquid crystal panel 3. The electrode terminals 4 are drawn out from the image display region (not shown) of the liquid crystal panel 3, and a predetermined voltage is applied to the electrode terminals 4, thereby applying a predetermined voltage to the pixels in the image display region of the liquid crystal panel 3 so as to change the orientation direction of the liquid crystal layer, and thus image display is performed.

On the electrode terminals 4 drawn out to the edge portion of the panel substrate 2, an insulation protective film 5 is formed to protect the electrode terminals 4 from corrosion due to contact with the air or the like and prevent an undesirable short circuit from occurring between the adjacent electrode terminals 4. As shown in FIG. 2, the insulation protective film 5 is not formed on a portion covered with the flexible printed circuit 10 where the electrode terminals 4 are connected thereto, and nor is it formed on a portion slightly closer to the image display region side than the portion covered with the flexible printed circuit 10. Thus, with the liquid crystal panel unit 100 according to the present embodiment, each of the electrode terminals 4 of the panel substrate 2 of the liquid crystal panel 3 has an electrode inspection region 8 that is exposed at a portion that is not covered with the flexible printed circuit 10.

The flexible printed circuit 10 has a wiring pattern 13 on the side where the flexible printed circuit 10 is joined to the panel substrate 2 on a base film 11, that is, the back face side in FIG. 2. The surface of the wiring pattern 13 on the panel substrate 2 side is covered with a protective layer 12 (not shown in FIG. 2), but at the portion of a connection portion 14 where an opening is formed in the protective layer 12 in the vicinity of the edge portion of the flexible printed circuit 10, the surface thereof is not covered with the protective layer 12 and is exposed toward the panel substrate 2.

Note that although the connection portion 14 where the wiring pattern 13 is exposed is coated with an ACF for physically and electrically connecting the wiring pattern 13 and the electrode terminals 4 of the panel substrate 2, illustration thereof is omitted in FIG. 2.

The base film 11 on which the wiring pattern 13 is formed has an opening portion 17 formed in a portion where the wiring pattern 13 is formed, and the wiring pattern 13 is also exposed toward the back face of the flexible printed circuit 10 at the opening portion 17. The portion where the wiring pattern 13 is exposed forms a wiring inspection region 18. Note that in FIG. 2, although the shape of the opening portion 17 is shown as a circle, the present invention is not limited to this, and there is no limitation to the shape thereof, which could be an oval, an ellipse, a quadrate such as a square or a rectangle, a triangle, or a polygon having five or more sides.

FIG. 3 is a partial enlarged sectional view showing a cross-sectional configuration of a portion where the panel substrate 2 of the liquid crystal panel 3 and the flexible printed circuit 10 are joined to each other, which corresponds to the portion shown by arrowed line A-A in FIG. 2.

The electrode terminals 4 drawn out from the display region and for applying a predetermined voltage to the electric circuit elements (not shown) inside the panel substrate 2 are formed on the panel substrate 2. The insulation protective film 5 is formed on the electrode terminals 4 so as to prevent the occurrence of undesirable short circuit failure caused by corrosion of the electrode terminals 4 due to being in contact with the air or adhesion of a conductive member on the electrode terminals 4.

As also described using FIG. 2, with the liquid crystal panel unit 100 according to the present embodiment, the insulation protective film 5 is not formed at the portion where the electrode terminals 4 are covered with the flexible printed circuit 10, nor at the electrode inspection region 8.

The flexible printed circuit 10 is connected in a region of the edge portion of the electrode terminals 4 where the insulation protective film 5 is not formed such that the wiring pattern 13 formed on the base film 11 faces the panel substrate 2. Although the protective layer 12 that protects the wiring pattern 13 is formed on the wiring pattern 13, an opening is formed in the protective layer 12 in a portion in the vicinity of the edge portion of the flexible printed circuit 10, and the connection portion 14 where the wiring pattern 13 is exposed toward the panel substrate 2 are formed. An ACF (anisotropic conductive film) in which conductive particles 16 are mixed in a resin layer 15 is formed in the opening portion of the protective layer 12 where the wiring pattern 13 is exposed, and the conductive particles 16 in the ACF are brought into contact with the surface of both the electrode terminal 4 and the wiring pattern 13 that are exposed toward each other, thereby establishing continuity therebetween. Further, the resin layer 15 of the ACF physically fixes the panel substrate 2 and the flexible printed circuit 10.

The base film 11 of the flexible printed circuit 10 has the opening portion 17 formed at the position overlapping with the wiring pattern 13, and has the wiring inspection region 18 formed where the wiring pattern 13 is exposed at the portion of the opening portion 17.

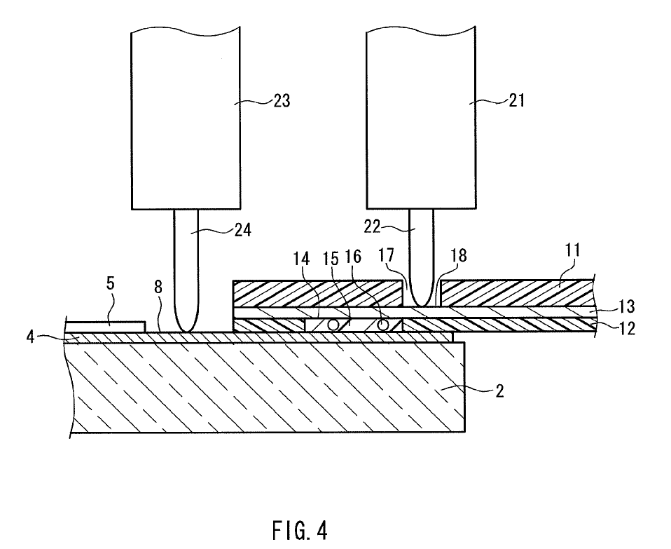

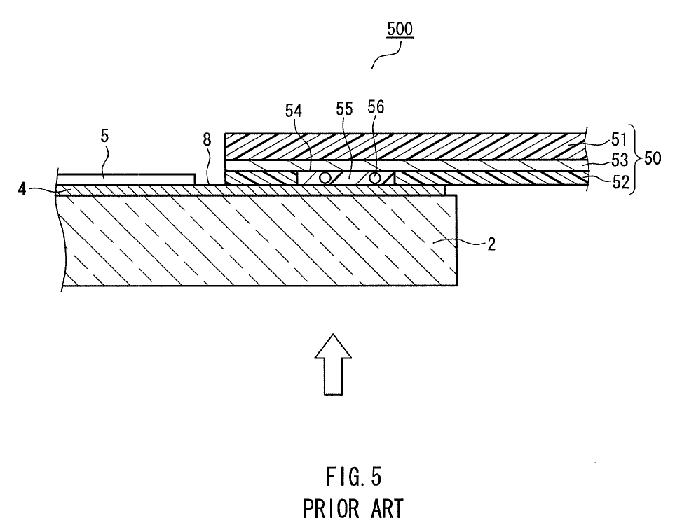

Next, a method for inspecting the liquid crystal panel unit of the present invention is described using FIG. 4. Note that in FIG. 4, both the panel substrate 2 of the liquid crystal panel and the flexible printed circuit 10 and the joined state thereof are the same as those shown in FIG. 3, and thus a description thereof is omitted.

An inspection using the method for inspecting the liquid crystal panel unit of the present invention is performed by directly detecting a resistance value between the electrode inspection region 8 of the electrode terminal 4 formed on the panel substrate 2 and the wiring inspection region 18 formed such that the wiring pattern 13 of the flexible printed circuit 10 laminated and fixed on the panel substrate 2 is exposed. FIG. 4 shows the state where an electrode inspection terminal 24 of an electrode inspection probe 23 is pressed against the electrode inspection region 8, and a wiring inspection terminal 22 of a wiring inspection probe 21 is pressed against the wiring inspection region 18, as an example of a specific method for measuring a resistance value between the electrode inspection region 8 and the wiring inspection region 18.

In this way, a resistance value between the electrode terminal 4 on the panel substrate 2 and the wiring pattern 13 of the flexible printed circuit 10 can be directly detected by applying a predetermined voltage between the electrode terminal 4 and the wiring pattern 13 and measuring the value of a current that flows between the electrode inspection terminal 24 and the wiring inspection terminal 22, using the electrode inspection terminal 24 and the wiring inspection terminal 22.

In fact, a plurality of the electrode inspection terminal 24 and a plurality of the wiring inspection terminal 22 shown in FIG. 4 are arranged and disposed in accordance with the pitch of the electrode terminals 4, and by respectively applying the predetermined inspection voltage and detecting the value of the current that flows, the connected state of the electrode terminals 4 and the wiring pattern 13 can be measured for the plurality of terminals at the same time and further based on a quantitative value, that is, a resistance value.

Accordingly, inspection failures that occur with the impression inspection method conventionally used are eliminated, and an inspection for continuity between the panel substrate of the liquid crystal panel and the flexible printed circuit can be performed accurately and simply.

Note that a description has been given in the above embodiment using an example in which the wiring inspection region 18 is formed at the position where the flexible printed circuit 10 overlaps the panel substrate 2 in the state where the flexible printed circuit 10 is laminated on the panel substrate 2, specifically, at the position where a relationship that the wiring inspection region 18 mounts the panel substrate 2. This allows, for example, the wiring inspection terminal 22 used when measuring a resistance value to be easily and reliably pressed against the wiring inspection region 18 of the wiring pattern 13.

However, the liquid crystal panel unit 100 of the present invention is not limited to this, and the opening portion 17 provided in the base film 11 of the flexible printed circuit 10, which will specify the position of the wiring inspection region 18, can be formed at a position other than the portion where the flexible printed circuit 10 and the panel substrate 2 overlap when the flexible printed circuit 10 is connected. In particular, the liquid crystal panel unit 100 is required to have a so-called frame area, which is an area at the periphery of the panel substrate 2 other than the image display region, that is reduced in size as much as possible, and thus it is preferable that a portion where the flexible printed circuit 10 and the panel substrate 2 overlap is limited to a minimum necessary area for connecting the flexible printed circuit 10.

Note that in the case where the wiring inspection region 18 is formed on the flexible printed circuit 10 at the position where the flexible printed circuit 10 and the panel substrate 2 do not overlap when the flexible printed circuit 10 is fixed to the panel substrate 2, it is preferable that a predetermined jig is provided on the back face of the wiring inspection region 18 during measurement so that the wiring pattern 13 and the wiring inspection terminal 22 can be reliably brought into contact with each other.

It is preferable to cover the top of the exposed electrode inspection region 8 with resin or the like after an inspection with regard to the connected state of the liquid crystal panel 3 and the flexible printed circuit 10 has ended.

### INDUSTRIAL APPLICABILITY

The liquid crystal panel unit of the present invention is industrially applicable as a liquid crystal panel unit with which the connected state of a liquid crystal panel and a flexible printed circuit can be easily and reliably inspected, and further, a method for inspecting the liquid crystal panel unit of the present invention is industrially applicable as a method that enables the connected state of the panel substrate and the flexible printed circuit to be easily and reliably inspected.

1. A liquid crystal panel unit, comprising:
a liquid crystal panel that has a panel substrate and an opposite substrate disposed opposite the panel substrate via a liquid crystal layer; and
a flexible printed circuit in which a connection portion of a wiring pattern is connected to an electrode terminal formed on the panel substrate,
wherein the electrode terminal has an electrode inspection region that is exposed in a state where the flexible printed circuit is connected, and
an opening portion that exposes the wiring pattern is formed in a base film of the flexible printed circuit.

2. The liquid crystal panel unit according to claim 1,
wherein the opening portion is formed at a position where the flexible printed circuit overlaps the panel substrate in a state where the flexible printed circuit is connected to the panel substrate.

3. A method for inspecting a liquid crystal panel unit including a liquid crystal panel that has a panel substrate and an opposite substrate disposed opposite the panel substrate via a liquid crystal layer, and a flexible printed circuit in which a connection portion of a wiring pattern is connected to an electrode terminal formed on the panel substrate, the method comprising:
detecting a resistance value between an electrode inspection region of the electrode terminal that is exposed in a state where the flexible printed circuit is connected and a wiring inspection region of the wiring pattern that is exposed by an opening portion being formed in a base film of the flexible printed circuit.

4. The method for inspecting the liquid crystal panel unit according to claim 3,
wherein a resistance value between the electrode terminal on the panel substrate and the wiring pattern of the flexible printed circuit is detected by bringing an inspection probe terminal into contact with each of the electrode inspection region and the wiring inspection region.

5. The method for inspecting the liquid crystal panel unit according to claim 3,
wherein the wiring inspection region is positioned in a portion where the flexible printed circuit and the panel substrate overlap in a state where the flexible printed circuit is connected to the panel substrate.
